(19) United States
(12) Patent Application Publication
(10) Pub. No.: US 2010/0182740 A1
(43) Pub. Date: Jul. 22, 2010

(54) DISPLAY AND INPUT DEVICE AND METHOD FOR MANUFACTURING THE SAME

(75) Inventor: Kenji ARITA, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: MITSUBISHI ELECTRIC CORPORATION, Chiyoda-ku (JP)

(21) Appl. No.: 12/685,914

(22) Filed: Jan. 12, 2010

(30) Foreign Application Priority Data
Jan. 21, 2009 (JP) 2009-010858

(51) Int. Cl. H05K 5/00

(52) U.S. Cl. 361/679.01

(57) ABSTRACT

An alignment mark is placed in a position adjacent to at least one of the four corners of an opening of a frame, of a touch panel in a manner corresponding to edges of the opening of the frame. The alignment mark placed on the touch panel is aligned with the edges of the opening made on the upper part of the frame. This allows accurate aligning of the touch panel on the display element.

### INCORPORATION BY REFERENCE

This application is based upon and claims the benefit of priority from Japanese patent application No. 2009-010858, filed on Jan. 21, 2009, the disclosure of which is incorporated herein in its entirety by reference.

### BACKGROUND OF THE INVENTION

1. Field of the Invention

The present invention relates to a display and input device and method for manufacturing the same. Particularly, present invention relates to a display and input device that includes an optically transparent substrate attached on the display surface of a display element, and method for manufacturing the same.

2. Description of Related Art

Display and input devices where a touch panel is attached on the display surface of a display device have been widely used in recent years. Typical examples thereof include mobile terminals and automatic teller machines (ATMs) for banks. Among major industrial applications thereof are operation panels of apparatuses. One of the reasons why display and input devices have been widely used is that all ages from children to elderly people can easily operate complicated computers without knowledge about such computers.

On the other hand, display and input devices as described above have a problem that inaccurate attaching of a touch panel on a display device hampers accurate input operations. In view of the foregoing, there is disclosed a technology that forms an alignment mark on the transparent area of a touch panel and provides signals into the display area of a display element to display an alignment pattern so as to align the alignment mark with the alignment pattern

(Japanese Unexamined Patent Application Publication No. 2008-9054 (pp. 7 to 8, FIGS. 1 to 7)).

Specifically, Japanese Unexamined Patent Application Publication No. 2008-9054 discloses a display device that is manufactured by forming an alignment mark on the display area of a touch panel using, for example, the transparent material of a transparent substrate, providing signals to a display element to display an alignment pattern, and aligning the alignment mark with the alignment pattern based on image recognition. However, we have now discovered that the alignment mark is difficult to recognize as an image, since it is formed of the transparent material. Also, an apparatus is required to provide signals to the display element to display the alignment pattern, resulting in complication of the manufacturing process. Also, the formation of the alignment mark increases the manufacturing process steps.

Among other methods for attaching a touch panel on a display device is a method of aligning outer edges of a touch panel and outer edges of a display device using, for example, an alignment guide.

Specifically, a touch panel is attached on a display device while pressing outer edges of the touch panel against an alignment guide, which is provided on a jig for fixing the display device and is intended to attach the touch panel on a predetermined position. In this method, the touch panel is manually pressed against the alignment guide. Accordingly, depending on how to apply a force to the touch panel, the touch panel and display device may be misaligned. Also, after attaching the touch panel, whether it is attached on a predetermined position accurately cannot be checked visually.

An advantage of the present invention is to provide a display and input device that includes an optically transparent substrate, such as a touch panel, attached on the display surface of a display element and can accurately align the display element and the optically transparent substrate without increasing manufacturing process steps, and a method for manufacturing the same.

### SUMMARY OF THE INVENTION

A first exemplary aspect of the present invention is a display and input device that includes a display element, a frame having a rectangular opening for holding the display element, and an optically transparent substrate disposed as opposed to the frame, wherein an alignment mark is placed on the substrate in a manner corresponding to the opening of the optically transparent frame.

A second exemplary aspect of the present invention is a method for manufacturing a display and input device that includes a display element, a frame having a rectangular opening for holding the display element, and an optically transparent substrate disposed as opposed to the frame. The method includes steps of aligning an alignment mark placed on the optically transparent substrate with the opening of the frame or an alignment mark placed on the frame, and attaching the optically transparent substrate to the frame.

According to the exemplary aspects of the present invention described above, it is possible to provide a display and input device that includes an optically transparent substrate attached on the display surface of a display element and a method for manufacturing the same which enable accurately align the display element and the optically transparent substrate without increasing manufacturing process steps.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a top view showing a display and input device according to an exemplary embodiment of the present invention;

FIG. 2 is a sectional view as seen in the direction of arrows II-II of FIG. 1;

FIG. 3 is an enlarged view of a III part of FIG. 1;

FIG. 4 is an enlarged view of a major part of a display and input device according to an exemplary embodiment of the present invention;

FIG. 5 is an enlarged view of a major part of a display and input device according to an exemplary embodiment of the present invention;

FIG. 6 is an enlarged view of a major part of a display and input device according to an exemplary embodiment of the present invention;

FIG. 7 is an enlarged view of a major part of a display and input device according to an exemplary embodiment of the present invention; and

FIG. 8 is an enlarged view of a VIII part of FIG. 7.

### DESCRIPTION OF THE EXEMPLARY EMBODIMENTS

### First Exemplary Embodiment

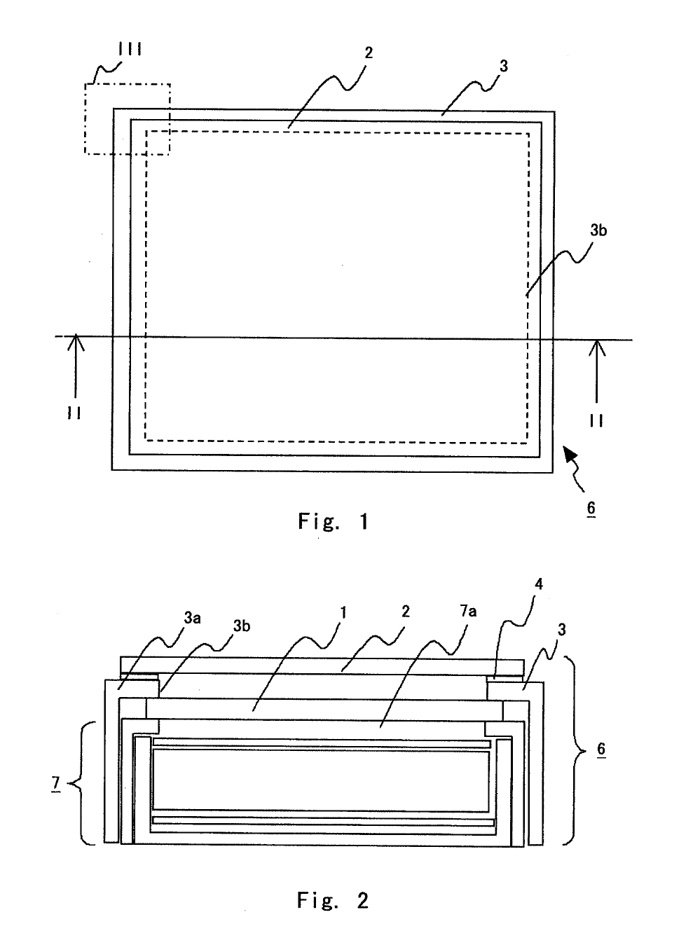

Now, a display and input device according to a first exemplary embodiment of the present invention will be described with reference to the accompanying drawings. FIG. 1 is a top view showing a state in which an optically transparent substrate such as a touch panel is disposed on a display device. FIG. 2 is a sectional view as seen in the direction of arrows II-II of FIG. 1. FIG. 3 is an enlarged view of a III part of FIG. 1. As shown in FIGS. 1 and 2, a display and input device 6 includes a backlight 7, a display element 1 that receives light from the backlight 7 via the back surface thereof, and a touch panel 2 that is an optically transparent substrate and is disposed as opposed to the display element 1. The display element 1 such as a liquid crystal panel is disposed as opposed to a light emitting surface 7a of the backlight 7. A frame 3 has a rectangular opening 3b on an upper part 3a thereof and holds the display element 1 and the backlight 7. The touch panel 2 is attached on the upper part 3a of the frame 3 with an adhesive material 4 such as a double-faced tape therebetween. The display and input device 6 is configured as described above.

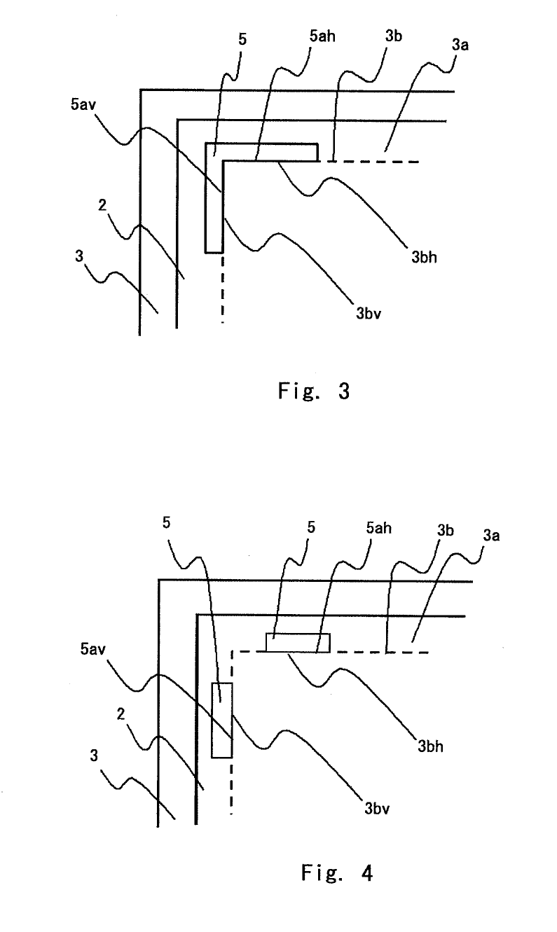

As shown in FIG. 3, in this exemplary embodiment, an alignment mark 5 is placed on the touch panel 2 to attach the touch panel 2 on a desired position of the upper part 3a of the frame 3. The alignment mark 5 is formed using a material for wiring formed in the touch panel 2, in the same process of forming the wiring. Also, the alignment mark 5 is placed in a position adjacent to at least one of the four corners of the opening 3b of the frame 3, of the touch panel 2 in a manner corresponding to edges of the opening 3b of the frame 3. The alignment mark 5 may be formed in the shape of an L having a horizontal edge 5ah corresponding to a horizontal edge 3bh of the opening 3b of the frame 3 and a vertical edge 5av corresponding to a vertical edge 3bv of the opening 3b. However, the alignment mark 5 does not always need to take the continuous shape (L shape) as long as it has the horizontal edge 5ah and vertical edge 5av as shown in FIG. 4 and may take various shapes. While the alignment mark 5 of the touch panel 2 is placed on the area outside the opening 3b of the frame 3 in this exemplary embodiment, it may be placed on the area inside the opening 3b. However, if the alignment mark 5 is disposed outside the operation area of the touch panel 2, a wide wiring pattern area can be ensured on the touch panel 2.

Next, the process of attaching the touch panel 2, on which the alignment mark 5 is placed, on the display element 1 will be described with reference to FIGS. 1 and 3. As shown in FIGS. 1 and 3, the display element 1 is disposed as opposed to the light emitting surface 7a of the backlight 7. Then, the frame 3 is disposed in a manner holding these elements. Then, the touch panel 2 is attached on the frame 3 with the adhesive material 4 such as a double-faced tape therebetween in such a manner that the alignment mark 5 placed on the touch panel 2 and the opening 3b of the frame 3 are aligned. At that time, the horizontal edge 5ah of the alignment mark 5 is aligned with the horizontal edge 3bh of the opening 3b of the frame 3. Similarly, the vertical edge 5av of the alignment mark 5 is aligned with the vertical edge 3bv of the opening 3b.

As described above, in the display and input device 6 according to the present invention, the alignment mark 5 placed on the touch panel 2 is aligned with the edges of the opening 3b made on the upper part 3a of the frame 3. This allows accurate aligning of the touch panel 2 on the display element. Also, the alignment mark 5 consists of the horizontal edge 5ah corresponding to the horizontal edge 3bh of the opening 3b of the frame 3 and the vertical edge 5av corresponding to the vertical edge 3bv of the opening 3b. This allows alignment of the touch panel 2 with the display element 1 in two directions, enabling more accurate aligning. Also, even after attaching the touch panel 2 on the upper part 3a of the frame 3, the attaching position can be visually checked for misalignment with ease.

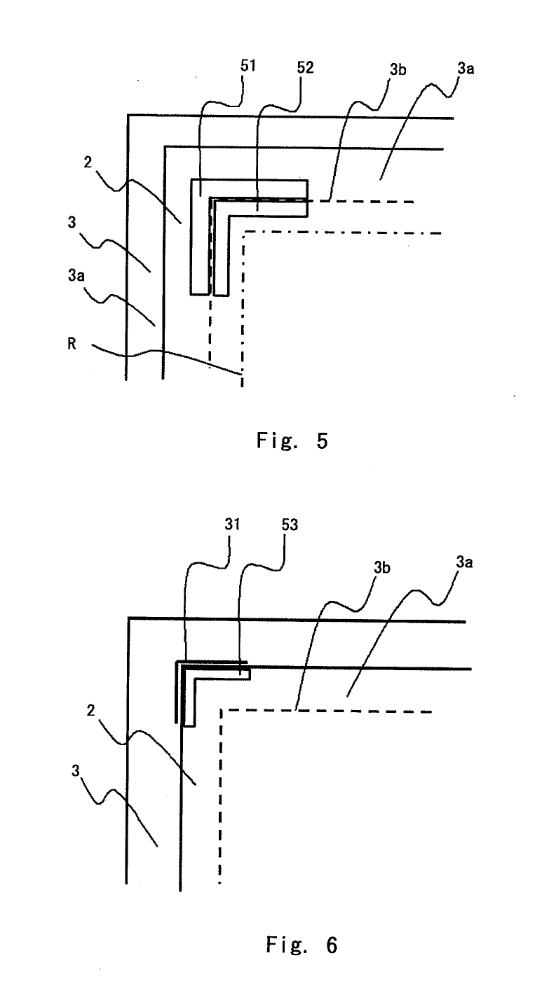

FIG. 5 shows a modification of the first exemplary embodiment. As shown in FIG. 5, in this modification, two alignment marks are placed, that is, an alignment mark 51 is placed outside the opening 3b of the frame 3 and an alignment mark 52 is placed inside the opening 3b. The touch panel 2 is attached on the upper part 3a of the frame 3 in such a manner that the edges of the opening 3b are disposed between the alignment marks 51 and 52 configured as described above. The second alignment mark 52 placed inside the opening 3b is disposed outside a display area R of the display element 1. As seen, the alignment of the alignment marks 51 and 52 with the horizontal edge 3bh and vertical edge 3bv of the opening 3b of the frame 3 allows more accurate aligning.

### Second Exemplary Embodiment

FIG. 6 shows an enlarged view of a major part of a second exemplary embodiment of the present invention. In the first exemplary embodiment, the alignment mark is placed on the position adjacent to one corner of the opening 3b of the frame 3, of the touch panel 2. On the other hand, in the second exemplary embodiment, an alignment mark 53 is placed adjacent to edges of the touch panel 2 and an alignment mark 31 is placed on a position corresponding to the alignment mark 53, of the upper part 3a of the frame 3. The alignment mark 31 may be formed on the frame 3 during the process of performing pressing or the like on the frame 3. The alignment mark 31 is formed using an inscription, such a scribed line, printing, or the like. By aligning the alignment mark 53 placed on the touch panel 2 with the alignment mark 31 placed on the frame 3, the touch panel 2 can be attached on a desired position of the frame 3. The alignment mark 53 placed adjacent to the edges of the touch panel 2 has no effect on display, as well as facilitates a check for alignment. Also, since the alignment mark 53 is placed to recognize the edges of the touch panel 2, its position, shape, or the like may be changed.

### Third Exemplary Embodiment

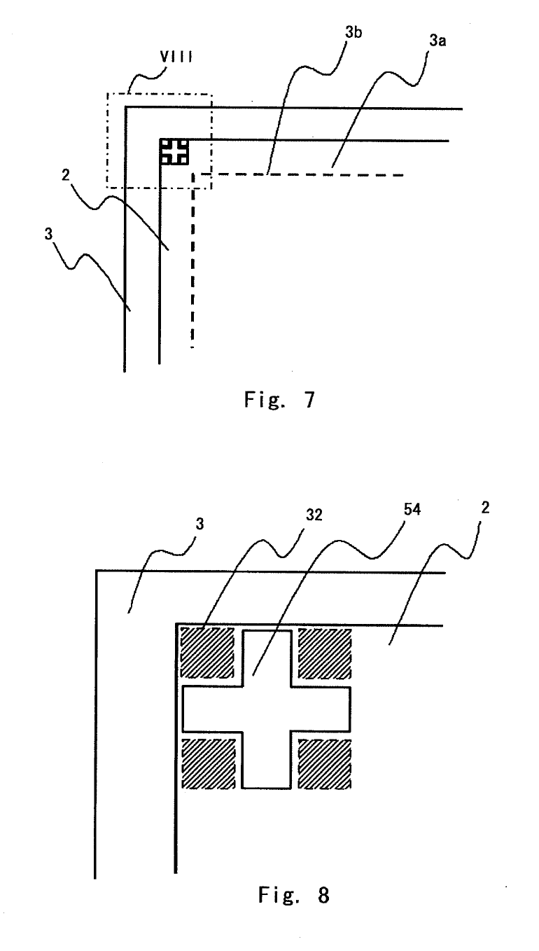

FIG. 7 is a drawing showing a third exemplary embodiment of the present invention. FIG. 8 is an enlarged view of a VIII part of FIG. 7. In the first exemplary embodiment, the alignment mark is placed in a manner corresponding to at least the horizontal and vertical edges of the opening 3b of the frame 3. On the other hand, in order to attach the touch panel and frame together more accurately using an apparatus, alignment marks as shown in FIGS. 7 and 8 may be placed. In FIG. 8, a cross-shaped alignment mark 54 is placed adjacent to edges of the touch panel 2. Also, four rectangular alignment marks 32 to form a rectangle with the cross-shaped alignment mark 54 are placed on the upper part 3a of the frame 3, on which the touch panel 2 is to be attached. By reading the alignment marks 32 and the alignment mark 54 using an image processing device and positioning the touch panel 2 and frame 3 using an automatic machine, the touch panel 2 can be attached more accurately than attached manually.

If the alignment marks according to the present invention are also placed in a diagonal position, the touch panel 2 can be attached more accurately. Furthermore, if the alignment marks are placed in all the corners, the touch panel 2 can be attached much more accurately. Also, by changing the width and length of the alignment marks, the distance between the opposed marks, or the like as appropriate, the attaching method can be changed between manual attaching and attaching using an automatic machine. Also, the alignment mark of the touch panel may be placed on any of the surface opposed to the display device and the surface thereof remote from the display device.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A display and input device comprising:
a display element;
a frame having a rectangular opening for holding the display element; and
an optically transparent substrate disposed as opposed to the frame, wherein
an alignment mark is placed on the optically transparent substrate in a manner corresponding to the opening of the frame.

2. The display and input device according to claim 1, wherein the alignment mark has a second horizontal edge and a second vertical edge corresponding to a first horizontal edge and a first vertical edge of the opening of the frame.

3. The display and input device according to claim 2, wherein the alignment mark takes the shape of an L having the second horizontal edge and the second vertical edge.

4. A display and input device comprising:
a display element;
a frame having a rectangular opening for holding the display element; and
an optically transparent substrate disposed as opposed to the frame, wherein
a first alignment mark is placed adjacent to an edge of the optically transparent substrate, and a second alignment mark is placed on a position corresponding to the first alignment mark, of the frame.

5. The display and input device according to claim 4, wherein
the first alignment mark has a horizontal edge and a vertical edge, and
the second alignment mark is placed in a manner corresponding to the horizontal edge and the vertical edge of the first alignment mark.

6. The display and input device according to claim 4, wherein
the first alignment mark takes the shape of a cross, and
the second alignment mark takes the shape of a rectangle to correspond to the cross-shaped first alignment mark.

7. A method for manufacturing a display and input device including a display element, a frame having a rectangular opening for holding the display element, and an optically transparent substrate disposed as opposed to the frame, the method comprising steps of:
aligning an alignment mark placed on the optically transparent substrate with the opening of the frame or an alignment mark placed on the frame; and
attaching the optically transparent substrate to the frame.
